(19) United States
(12) Patent Application Publication
(10) Pub. No.: US 2007/0287075 A1
(43) Pub. Date: Dec. 13, 2007

(54) Mask arrangement, optical projection system and method for obtaining grating parameters and absorption properties of a diffractive optical element

(76) Inventors: Rainer Pforr, Dresden (DE); Jens Reichelt, Dresden (DE); Mario Hennig, Dresden (DE); Thomas Mulders, Dresden (DE); Karsten Zeiler, Munchen (DE)

Correspondence Address: EDELL, SHAPIRO & FINNAN, LLC, 1901 RESEARCH BLVD., SUITE 400, ROCKVILLE, MD, 20850, US

(21) Appl. No.: 11/451,618

(22) Filed: Jun. 13, 2006

(51) Int. Cl. G03B 27/42; G03F 1/00

(52) U.S. Cl. 430/5; 355/53

(57) ABSTRACT

A mask arrangement or an optical projection system includes a diffractive optical element. The diffractive optical element includes grid sections having gratings with defined grating parameters and absorbing elements with defined absorption properties, wherein each grid section corresponds to a respective mask section with mask pattern elements. The diffractive optical element may correct dimension deviations of resist pattern elements obtained from the respective mask pattern elements, wherein the deviations are caused by dimension deviations of the mask pattern elements or by local deviations and defects of the projection system.

### BACKGROUND OF THE INVENTION

Projection photolithography techniques transfer a mask pattern comprising mask pattern elements having a length and a width onto a photoresist layer covering a semiconductor wafer through an optical projection system.

Local deviations in the dimensions of the mask pattern elements from target dimensions, aberrations of the optical projection system across the imaging field, deviations in the polarization characteristics of the light used in the optical projection system, and small deviations in the illumination source distribution cause large dimension deviations of resist pattern elements being obtained from the respective mask pattern elements in the photoresist layer. Thus, large dimension deviations of the resist pattern elements from target dimensions may occur across the imaging field of the projection system. Differently stated, local dimension deviations of the resist pattern elements from target dimensions obtained at other locations by projecting mask patterns onto a photoresist layer may occur.

### SUMMARY OF THE INVENTION

According to a first embodiment of the present invention, a mask arrangement for an optical projection system for projecting light absorbing patterns onto a photoresist layer comprises a photomask and a diffractive optical element. The photomask comprises a transparent mask substrate and a light absorber pattern. The light absorber pattern includes at least a first mask section with a first mask pattern element and a second mask section with a second mask pattern element. The first and the second mask pattern elements have essentially the same shape and size. From the first mask pattern element, a first resist pattern element in the photoresist layer is obtained, and from the second mask pattern element, a second resist pattern element in the photoresist layer is obtained. The first mask pattern element has a first length and a first width and the second mask pattern element has a second length and a second width, wherein at least the second length or the second width is different from the first length and the first width, respectively.

The diffractive optical element is positioned in an optical path between a light source of the optical projection system and the photomask. The diffractive optical element includes at least a first grid section corresponding to the first mask section and comprising a first grating and a first absorbing element, and a second grid section corresponding to the second mask section and comprising a second grating and a second absorbing element. Each grating has grating parameters and each absorbing element has absorption properties such that the first and the second resist pattern elements have the same length and width.

The diffractive optical element of the mask arrangement locally changes the illumination source distribution of the light (radiation) passing the photomask by diffraction of the light at the gratings and by absorption due to the absorbing elements such that the second resist pattern element that is obtained from the second mask pattern element has the same length and width as the first resist pattern element that is obtained from the first mask pattern element, although the first and the second mask pattern elements have at least a different length or width. Thus, dimension deviations of the resist pattern elements from target dimensions caused by dimension deviations of the respective mask pattern elements may be corrected. A correction of the length or the width of the resist pattern elements or of the ratio of length to width may be achieved in a locally restricted (effective) manner. The diffractive optical element of this embodiment is adapted to the properties of the photomask of the respective mask arrangement.

Dimension deviations of mask pattern elements of a photomask may be corrected by locally changing the illumination source distribution of the projecting light. The diffractive optical element corrects in general both dimensions (length and width) independently from each other.

According to a second embodiment of the present invention, an optical projection system for projecting light absorber patterns onto a photoresist layer comprises an illumination system, optical elements, a photomask, a projection lens mechanism, and a diffractive optical element. The illumination system includes a light source emitting light. The optical elements define an illumination source distribution and a polarization characteristic of the light. The photomask is positioned in an optical path of the illumination system and comprises a transparent mask substrate and a light absorber pattern. The light absorber pattern has at least a first and a second mask section with first and second mask pattern elements, having the same lengths and widths, respectively. The projection lens mechanism projects the mask pattern elements onto the photoresist layer on a surface of a substrate. Defects and production tolerances of the optical elements and/or the projection lens mechanism cause deviations in the illumination source distribution and/or the polarization characteristic and/or the projection of the mask pattern elements. Furthermore, deviations in the glass optics of the optical elements and projection lens means, like birefringence effects, may cause deviations in the illumination source distribution and/or the polarization characteristic and/or the projection of the mask pattern elements.

The diffractive optical element is positioned in the optical path between the light source of the illumination system and the photomask. The diffractive optical element includes at least a first grid section corresponding to the first mask section and comprising a first grating and a first absorbing element, and a second grid section corresponding to the second mask section and comprising a second grating and a second absorbing element. Each grating has grating parameters and each absorbing element has absorption properties that are respectively determined such that the resist pattern elements obtained from the mask pattern elements of the first and the second mask sections have the same length and the same width.

The diffractive optical element of the optical projection system locally changes the illumination source distribution of the light passing the photomask by diffraction of the light at the gratings and by absorption due to the absorbing elements such that the resulting resist pattern elements that are obtained from mask pattern elements positioned in different mask sections of the photomask have the same length and width. Thus, dimension deviations of resist pattern elements from target dimensions caused by locally restricted deviations of the projection system may be corrected. A correction of the length or the width of the resist pattern elements or of both in a predetermined ratio may be achieved in a locally restricted manner. The diffractive optical element according to this embodiment is adapted to the optical elements and/or the projection lens mechanism of the respective projection system.

Deviations in the projection of mask pattern elements caused by the projection system may be corrected by locally changing the illumination source distribution of the projecting light through the diffractive optical element. The correction may be performed for both dimensions (length and width) independently from each other.

According to a third embodiment of the present invention, an optical projection system for projecting light absorber patterns onto a photoresist layer comprises an illumination system, optical elements, a photomask, a projection lens mechanism, and a diffractive optical element. The illumination system includes a light source emitting light. The optical elements define an illumination source distribution and a polarization characteristic of the light. The photomask is positioned in an optical path of the illumination system and comprises a transparent mask substrate and a light absorber pattern. The light absorber pattern includes at least a first mask section with a first mask pattern element and a second mask section with a second mask pattern element. The first and the second mask pattern elements have essentially the same shape and size. From the first mask pattern element, a first resist pattern element in the photoresist layer is obtained, and from the second mask pattern element, a second resist pattern element in the photoresist layer is obtained. The first mask pattern element has a first length and a first width and the second mask pattern element has a second length and a second width. At least the second length or the second width is different from the first length and the first width, respectively.

The projection lens mechanism projects the mask pattern elements onto the photoresist layer covering a surface of a substrate. The optical elements or the projection lens mechanism causes deviations in the illumination source distribution and/or the polarization characteristic and/or the projection of the first and second mask pattern elements.

The diffractive optical element is positioned in the optical path between the light source of the illumination system and the photomask. The diffractive optical element comprises at least a first section corresponding to the first mask section and including a first grating and a first absorbing element, and a second section corresponding to the second mask section and including a second grating and a second absorbing element. Each grating has grating parameters and each absorbing element has absorption properties that are respectively determined such that the first and second resist pattern elements have the same length and the same width.

The diffractive optical element of the optical projection system according to the third embodiment combines the properties of the diffractive optical elements according to the first and the second embodiment. Differently stated, there are first and a second mask sections with first and second mask pattern elements, respectively, from which first and second resist pattern elements are obtained. The second mask pattern element has at least a different length or width with respect to first mask pattern element. Further, deviations in the optical elements and/or the projection lens mechanism of the projection system cause deviations in the illumination source distribution and/or the polarization characteristic and/or the projection of the mask pattern elements. Therefore, first and second mask pattern elements are imaged differently. Respective grid sections in the diffractive optical element locally change the illumination source distribution of the light passing the photomask by diffraction of the light at the respective gratings and by absorption due to the respective absorbing elements. The parameters of the gratings and the properties of the absorbing elements are determined such that the second resist pattern element has the same length and width as the first resist pattern element.

Thus, dimension deviations of resist pattern elements from target dimensions caused by dimension deviations of the mask pattern elements and caused by local deviations of the projection system may be corrected. A correction of the length or the width of single resist pattern elements or of a plurality of resist pattern elements in a predetermined ratio may be achieved in a locally restricted manner. The diffractive optical element according to this embodiment is adapted to the photomask and to the optical elements and the projection lens mechanism of the respective projection system.

The diffractive optical element of the third embodiment combines the advantages of the diffractive optical elements of the first and the second embodiment.

According to a fourth embodiment of the present invention, an optical projection system for projecting light absorber patterns onto a photoresist layer comprises an illumination system, optical elements, a photomask, a projection lens mechanism, and a diffractive optical element. The illumination system includes a light source emitting light. The optical elements define an illumination source distribution and a polarization characteristic of the light. The photomask is positioned in an optical path of the illumination system and comprises a transparent mask substrate and a light absorber pattern. The light absorber pattern includes at least a first mask section with a first mask pattern element and a second mask section with a second mask pattern element. A first resist pattern element in the photoresist layer is obtained from the first mask pattern element, and a second resist pattern element in the photoresist layer is obtained from the second mask pattern element. The first mask pattern element has a first length and a first width and the second mask pattern element has a second length and a second width in a predetermined ratio to the first length and width respectively. The projection lens mechanism projects the mask pattern elements onto the photoresist layer covering a surface of a substrate. The projection of the mask pattern elements in the first and the second mask section are different.

The diffractive optical element is positioned in the optical path between the light source of the illumination system and the photomask. The diffractive optical element comprises at least a first section corresponding to the first mask section and including a first grating and a first absorbing element and a second section corresponding to the second mask section and including a second grating and a second absorbing element. Each grating has grating parameters and each absorbing element has absorption properties that are respectively determined such that the first resist pattern element has a length and a width in a predetermined ratio to the length and the width of the second resist pattern element respectively.

The diffractive optical element of the optical projection system according to the fourth embodiment corrects differences in the projection of different mask pattern elements, i.e., elements having different shape and/or size. Although these differences may be considered in the design of the mask pattern elements, the design is based on a defined assumption of a projection of the mask pattern elements. In the case that these assumptions are no longer valid (for instance because different projection systems result in different projection properties), the projection of different mask pattern elements may not be optimized such that all mask pattern elements are projected in the correct manner. Therefore, different resist pattern elements may not have dimensions in a predetermined ratio. This can be corrected by a corresponding diffractive optical element. Respective grid sections in the diffractive optical element locally change the illumination source distribution of the light passing the photomask by diffraction of the light at the respective gratings and by absorption due to the respective absorbing elements. The parameters of the gratings and the properties of the absorbing elements are determined such that the second resist pattern elements have a length and a width in a predetermined ratio to the length and the width of the first resist pattern elements.

The diffractive optical element according to this embodiment is adapted to the photomask and to the used projection system.

The diffractive optical element of the fourth embodiment provides the possibility of correcting the projection of different mask pattern elements through a defined projection system without the need to change the design of the mask pattern elements. It may be combined with diffractive optical elements of the first to third embodiment of this invention, i.e., the parameters and properties of grid sections may be defined such that the diffractive optical element further corrects dimension deviations of resist pattern elements from target dimensions caused by dimension deviations of the mask pattern elements or caused by local deviations of the projection system.

According to another embodiment of the invention, methods for obtaining the grating parameters and absorption properties of the diffractive optical elements as described above are provided.

A method for obtaining the grating parameters and absorption properties of a diffractive optical element of the mask arrangement according to the first embodiment of the invention comprises providing the photomask of the mask arrangement and determining the dimensions of the respective mask pattern elements in the photomask.

The dimensions of the resist pattern elements obtained by projection of the mask pattern elements onto the photoresist are calculated using a simulation program, wherein a virtual diffractive optical element with first grating parameters and first absorption properties of each grid section is supposed in an simulated optical path of the simulation program. First dimensions of the resist pattern elements are obtained and compared with predetermined (desired) dimensions of the resist pattern elements.

The grating parameters and absorption properties of the grid sections of the virtual diffractive optical element are now varied in dependency on the differences between the respective calculated and the desired dimensions of the corresponding resist pattern elements. The dimensions of the resist pattern elements obtained from the mask pattern elements by projection onto a photoresist are calculated using the simulation program, wherein the virtual diffractive optical element with varied grating parameters and absorption properties for each grid section is supposed in the optical path. Second dimensions of the resist pattern elements are obtained.

The operations of comparing the calculated dimensions of the resist pattern elements with the respective desired dimensions, varying the grating parameters and absorption properties of the virtual diffractive optical element, and recalculating the dimensions of the resist pattern elements are repeated until the deviations of the calculated dimensions from the desired dimensions are within a predetermined range respectively. The last grating parameters and the last absorptions properties of each grid section of the diffractive optical element are stored if desired dimensions of resist pattern elements are obtained.

The stored grating parameters and absorption properties of the virtual diffractive optical element are the grating parameters and absorption properties of the diffractive optical element which is a part of the mask arrangement or the optical projection system according to the invention.

A method for obtaining the grating parameters and the absorption properties of the diffractive optical element of the optical projection system according to the second embodiment of the invention comprises providing the optical projection system, wherein the optical elements and/or the projection lens mechanism causes deviations in an illumination source distribution and/or a polarization characteristic and/or the optical projection of the mask pattern elements of the photomask.

Different sections of a photomask and at least one photoresist layer are provided. The mask pattern elements in the photomask are projected onto respective sections of the photoresist layer using the optical projection system. The photoresist layer is developed and resist pattern elements are obtained. Alternatively, two or more different photomasks and/or two or more different photoresist layers on two or more substrates may be provided.

The dimensions of the resist pattern elements are measured, and the measured dimensions of the resist pattern elements obtained from different sections of the photomask are compared. Thereby, the differences in the measured dimensions caused by differences in the dimensions of the respective mask pattern elements within the different sections of the photomask may be eliminated. The deviations caused by the optical elements or the projection lens mechanism of the optical projection system are calculated and stored.

Dimensions of resist pattern elements obtained from mask pattern elements in a photomask by projection onto a photoresist are calculated using a simulation program, wherein the mask pattern elements in the photomask have equal dimensions. A virtual diffractive optical element with first grating parameters and first absorption properties of each grid section is supposed in the optical path of the projection system while simulating the projection. The simulation program incorporates the stored deviations caused by the projection system. First dimensions of the resist pattern elements are obtained and compared with desired dimensions of the resist pattern elements.

The grating parameters and absorption properties of the grid sections of the virtual diffractive optical element are varied in dependency on the differences between the respective calculated and the desired dimensions of the corresponding resist pattern elements. The dimensions of the resist pattern elements obtained from the mask pattern elements in the photomask by projection onto a photoresist are calculated using the simulation program, wherein the virtual diffractive optical element with varied grating parameters and absorption properties for each grid section is supposed in the optical path. Second dimensions of the resist pattern elements are obtained.

The operations of comparing the calculated dimensions of the resist pattern elements with the respective desired dimensions, varying the grating parameters and absorption properties of the grid sections, and recalculating the dimensions of the resist pattern elements are repeated until the deviations of the calculated dimensions from the desired dimensions is within a predetermined range, respectively. The last grating parameters and the last absorptions properties of each grid section of the virtual diffractive optical element are stored if desired dimensions of the resist pattern elements are obtained.

A method for obtaining the grating parameters and the absorption properties of a diffractive optical element of the optical projection system according to the third embodiment of the invention comprises providing the optical projection system comprising the photomask and providing a photoresist layer.

Mask pattern elements in the photomask are projected into the photoresist layer using the optical projection system and the photoresist layer is developed. Thereby, resist pattern elements are obtained, and the dimensions of the resist pattern elements are measured.

The dimensions of resist pattern elements obtained from the mask pattern element in the photomask by projection onto a photoresist through the optical projection system are calculated using a simulation program with first program parameters. First dimensions of the resist pattern elements are obtained and compared with the measured dimensions of the resist pattern elements.

The program parameters of the simulation program are varied in dependency of the differences between the calculated and the measured dimensions of the resist pattern elements. The dimensions of the resist pattern elements are calculated using the simulation program with varied program parameters. Second dimensions of the resist pattern elements are obtained.

The operations of comparing the calculated dimensions with the measured dimensions, varying the program parameters, and recalculating the dimensions of the resist pattern elements are repeated as long as the calculated dimensions of the resist pattern elements are not equal to the measured dimensions of the resist pattern elements. The last program parameters of the simulation program are stored if the calculated dimensions of the resist pattern elements are equal to the measured dimensions of the resist pattern elements.

The dimensions of resist pattern elements obtained from the mask pattern elements in the photomask by projection onto a photoresist are calculated using a simulation program with the stored program parameters wherein a virtual diffractive optical element with first grating parameters and first absorption properties of each grid section is supposed in the optical path. Third dimensions of the resist pattern elements are obtained and compared with desired dimensions of the resist pattern elements.

The grating parameters and absorption properties of the grid sections of the virtual diffractive optical element are varied in dependency on the differences between the calculated and the desired dimensions of resist pattern elements. The dimensions of the resist pattern elements are calculated using the simulation program, wherein the virtual diffractive optical element with varied grating parameters is supposed in the optical path. Fourth dimensions of resist pattern elements are obtained.

The operations of comparing the calculated dimensions of the resist pattern elements with the respective desired dimensions, varying the grating parameters and absorption properties of the grid sections, and calculating the dimensions of the resist pattern elements are repeated until the deviations of the calculated dimensions from the desired dimensions is within a predetermined range respectively. The last grating parameters and the last absorptions properties of each grid section of the virtual diffractive optical element are stored if desired dimensions of the resist pattern elements are obtained.

Another embodiment of the invention refers to a mask arrangement or an optical projection system with a diffractive optical element comprising an antireflective coating (ARC) layer. The diffractive optical element comprises a transparent element substrate with a first surface facing the light source and a second surface facing the mask. At least one ARC layer is provided covering the first or the second surface of the element substrate. The ARC layer comprises at least a first layer section with a first layer thickness and a second layer section with a second layer thickness, wherein the first and the second thickness differ from each other. A grid layer covers the antireflective coating layer or the surface of the element substrate not being covered by the antireflective coating layer. The first grid section of the diffractive optical element corresponds to the first layer section and the second grid section corresponds to the second layer section.

Methods for obtaining the grating parameters and absorption properties of such a diffractive optical element include further operations. An initial optical element comprising the transparent element substrate and the at least one antireflective coating layer of the diffractive optical element is provided. The transmission properties of each element section of the initial optical element are determined, wherein each element section corresponds to a respective layer section of the ARC layer and a respective grid section of the diffractive optical element.

According to one embodiment, the simulation program used to calculate the dimensions of the resist pattern elements obtained by the mask pattern elements by projection onto a photoresist incorporates the determined transmission properties of the initial optical element. A supposed virtual diffractive optical element thus features the transmission properties of the initial optical element.

By repeating the steps of varying the grating parameters and absorption properties of the virtual diffractive optical element, calculating the dimensions of resist pattern elements and comparing them with predetermined (specified) dimensions, grating parameters and absorption properties of the virtual diffractive optical element are obtained that correct dimension variations of mask pattern elements and/or variations in the projection of mask pattern elements caused by the projection system as well as thickness variations of the ARC layer.

According to another embodiment, at first, grating parameters and absorption properties of a virtual diffractive optical element are determined as yet described for diffractive optical elements without ARC layer.

Next, absorption properties of each grid section of a virtual initial optical element for correction of the transmission variations caused by thickness variations in the ARC layer are determined. This is obtained by calculating the transmission properties of each element section of the virtual initial optical element using a simulation program. The virtual initial optical element features the determined transmission properties of the initial optical element. A grid layer is supposed on the surface of the virtual initial optical element. The grid layer comprises grid sections with absorbing elements, wherein each grid section corresponds to a respective element section and has first absorption properties.

The calculated transmission properties of each element section are compared. If they differ from each other, the absorption properties of corresponding grid sections are varied. Second transmission properties are calculated and compared with each other.

By repeating the operations of varying the absorption properties of grid sections of the virtual initial optical element, calculating the transmission properties for each element section, and comparing them with one another, absorption properties of each grid section of the virtual initial optical element are obtained that correct thickness variations of the ARC layer.

The grating parameters and the absorption properties of the virtual diffractive optical element and the absorption properties of the virtual initial optical element are then combined to obtain grating parameters and absorption properties of a diffractive optical element with one grid layer.

In another embodiment, a diffractive optical element comprises a first and a second grid layer, each grid layer comprising grid pattern elements. The first grid layer covers the antireflective coating layer or one of the antireflective coating layers. The second grid layer covers the first grid layer or the other antireflective coating layer or the surface of the element substrate not being covered by the antireflective coating layer. The first grid layer realizes the grating parameters and absorption properties of the virtual diffractive optical element, while the second grid layer realizes the absorption properties of the virtual initial optical element.

The diffractive optical element may comprise one or two grid layers. In both cases, it corrects dimension variations of mask pattern elements and/or variations in the projection of mask pattern elements caused by the projection system as well as thickness variations of the ARC layer.

According to another embodiment, at first, grating parameters and absorption properties of a virtual diffractive optical element are determined as yet described for diffractive optical elements without ARC layer.

Next, the absorption properties of each grid section of the virtual diffractive optical element are changed such that the transmission is reduced equally for all grid sections. The degree of reduction of the transmission corresponds to the assumed transmission variation across the ARC layer caused by thickness variations. The transmission reduction is realized by applying homogeneously additional absorbing structures across the whole diffractive optical element. Thereby, a changed virtual diffractive optical element is obtained. The grating parameters of each grid section of the changed virtual diffractive optical element are that of the respective grid sections of the virtual diffractive optical element and the absorption properties of each grid section of the changed virtual diffractive optical element are the changed absorption properties.

Next, an initial diffractive optical element comprising the transparent element substrate and the at least one ARC layer of the diffractive optical element and an initial grid layer disposed on the ARC layer is provided. The initial grid layer is formed of the material of the grid layer of the diffractive optical element. It is structured according to the grating parameters and to the absorption properties of the changed virtual diffractive optical element.

The mask pattern elements of a photomask are then projected onto a photoresist layer using an optical projection system. The photomask and the optical projection system are the ones for which grating parameters and absorption properties of the diffractive optical element were firstly determined. The structured initial diffractive optical element is positioned in the optical path between the light source of the illumination system of the optical projection system and the photomask. The photoresist is then developed and the dimensions of the obtained resist pattern elements are measured.

The measured dimensions of the resist pattern elements are compared with predetermined dimensions. Then, the absorption properties of the grid sections of the changed virtual diffractive optical element are varied in dependency on the difference between the measured and the predetermined dimensions.

The dimensions of the resist pattern elements obtained from the mask pattern elements by projection onto a photoresist are calculated using the simulation program, wherein the changed virtual diffractive optical element with varied absorption properties is supposed in the optical path. The calculated dimensions are compared with the predetermined dimensions.

By repeating the operations of varying the absorption properties of the grid sections of the changed virtual diffractive optical element, calculating the dimensions of the resist pattern elements and comparing them with the predetermined ones, absorption properties of each grid section of the changed virtual diffractive optical element are obtained that correct dimension variations of mask pattern elements and/or variations in the projection of mask pattern elements caused by the projection system as well as thickness variations of the ARC layer.

Subsequently the initial grid layer of the initial diffractive optical element is structured according to the absorption properties of each grid section of the changed virtual diffractive optical element.

The above and still further features and advantages of the present invention will become apparent upon consideration of the following descriptions and descriptive figures of specific embodiments thereof, wherein like reference numerals in the various figures are utilized to designate like components. The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated, as they become better understood by reference to the following detailed description. While these descriptions go into specific details of the invention, it should be understood that variations may and do exist and would be apparent to those skilled in the art based on the descriptions herein.

### BRIEF DESCRIPTION THE DRAWINGS

FIG. 1 is a plan view of a diffractive optical element with grid sections according to an exemplary embodiment of the invention.

FIG. 1A is an enlarged plan view of a section of the plan view of FIG. 1 showing the grid sections of the diffractive optical element.

FIGS. 2A to 2C are plan views of the grid sections of a diffractive optical element according to other exemplary embodiments of the invention.

FIG. 3 illustrates schematically an optical projection system with a diffractive optical element positioned at an exemplary position according to an embodiment of the invention.

FIG. 4 illustrates schematically an optical projection system with a diffractive optical element at another exemplary position according to a further embodiment of the invention.

FIG. 5 is a cross-sectional view of a photomask and a diffractive optical element according to an embodiment of the invention with the diffractive optical element fixed on the photomask.

FIGS. 6A to 6C show cross-sectional views of a diffractive optical element according to further embodiments of the invention.

FIG. 7 illustrates schematically the effect of a diffractive optical element according to an embodiment of the invention.

FIGS. 7A and 7B show the illumination source distribution in an optical projection system before and after the diffractive optical element according to an embodiment of the invention.

FIG. 8 shows a plan view on exemplary mask pattern elements.

FIGS. 9 to 11A show plan views on grid sections of a diffractive optical element with different grating parameters and absorption properties according to embodiments of the invention and corresponding resist pattern elements obtained from the mask pattern elements of FIG. 8.

Corresponding numerals in the different figures refer to corresponding parts and features unless otherwise indicated. The figures are drawn to clearly illustrate the relevant aspects of the preferred embodiments and are not necessarily in all respects drawn to scale.

### DETAILED DESCRIPTION OF THE INVENTION

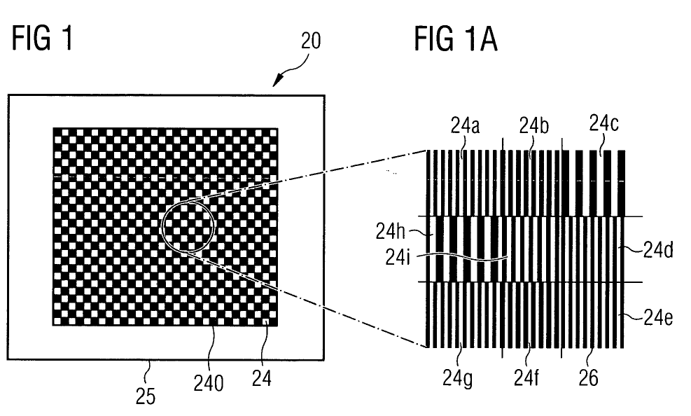

FIG. 1 shows a diffractive optical element 20 according to an exemplary embodiment of the present invention. The diffractive optical element 20 may be part of a mask arrangement according to a first aspect of the invention or part of an optical projection system according to another aspect of the invention. The diffractive optical element 20 includes an active region 240 and an edge region 25. In the edge region 25 a suspension mechanism (not shown) may be provided to fix the diffractive optical element 20 in a predetermined position with respect to a corresponding photomask or scanner optics (not shown). The active region 240 comprises a plurality of grid sections 24. Each grid section 24 corresponds to a mask section of the corresponding photomask (not shown), wherein each mask section comprises mask pattern elements, respectively.

FIG. 1A illustrates an enlarged section of the active region 240 with a plurality of grid sections 24a to 24i. Each grid section 24a to 24i comprises a grating and an absorbing element having defined grating parameters and absorption properties, respectively. The grating parameters and absorption properties of each grid section 24a to 24i correspond to the desired dimension correction of resist pattern elements obtained from the respective mask pattern elements. A first mask section comprises a first mask pattern element and a second mask section comprises a second mask pattern element, wherein the first and the second mask pattern elements have essentially the same shape and size. Differently stated, both mask pattern elements are elements of the same type, like elements for trench openings, contact vias or landing pads of electronic devices, for instance, that have slightly different dimensions. The mask pattern elements may be of any type of element, but typically the dimensions of these elements and their homogeneity across the imaging field or/and the wafer are critical and have to be in a defined range in order to achieve high yield and performance of electronic devices.

If the dimensions of the resist pattern elements obtained from the mask pattern elements of the first and second mask section deviate from the desired dimensions and the deviation may not be compensated for both mask sections by changing the projection parameters, like illumination source distribution, numerical aperture or exposure dose for example, a locally restricted change of projection parameters for one or both mask sections is desired.

The deviations may be caused by different dimensions of the mask pattern elements. Furthermore, different dimensions of resist pattern elements may be obtained even from mask pattern elements having the same dimensions due to deviations in the projection of the mask pattern elements onto the photoresist, wherein the deviations are caused by defects or production imperfections of the illumination optic and/or projection lens mechanisms of the whole projection system. Furthermore, the deviations of the dimensions of the resist pattern elements caused by imperfections of the projection system may not be the same for both dimensions of two-dimensional pattern elements. Differently stated, the length and the width of the resist pattern elements may vary from the desired dimensions in a different ratio.

A local correction of the dimensions of the resist pattern elements may be achieved by locally changing illumination source distribution through a corresponding grid section in the diffractive optical element. Therefore, each grid section has defined grating parameters, like the width and the period of the grating lines or their orientation for example, and defined absorption properties. The grating parameters and absorption properties may be defined by the shape and the orientation of the grating elements, by the thickness and the optical properties (e.g., refractive index, absorption coefficient) of the material of the gratings, and by the absorption element as well. The grid sections may comprise linear gratings, differently-shaped grating elements, semi-transparent phase-shifting elements, transparent elements or two-dimensional gratings. Thus, the length or the width of a resist pattern element may be corrected independently from one another or the length and the width may be corrected in a defined ratio such that resist pattern elements obtained from mask pattern elements of different mask sections have the same specified (predetermined) dimensions.

The absorbing elements of the grid sections of the diffractive optical element may include a two-dimensional grating (checkerboard-like gratings) or statistically distributed absorbing structures. The grating parameters of the respective two-dimensional gratings or the shape and the density of the absorbing structures are defined such that desired absorbing properties of the absorbing element of each grid section are achieved.

If only one dimension of a first resist pattern element differs from the corresponding dimension of a second resist pattern element and the dimensions of the first resist pattern element has specified, predetermined dimensions, the second grid section of the diffractive optical element may comprise a second grating. The absorption properties of the second absorbing element may be equal to that of the absorption properties of the first absorbing element comprised in the first grid section of the diffractive optical element.

Referring again to FIG. 1, the active region 240 of the diffractive optical element 20 may comprise a plurality of grid sections 24 having the same shape and the same size. The grid sections 24 may also have different shape and size. Exemplarily, the size of the grid sections 24 may be in the range of about (5×5) μm² to about (500×500) μm². In one embodiment, the size is about (100×100) μm².

Referring again to FIG. 1A, the grid sections 24a to 24i have gratings 26 with different grating parameters, while the absorption properties of the grid sections are essentially the same. Each grating 26 has a pattern of parallel opaque, transparent and/or semitransparent grating lines. The grating lines fill the whole area of grid sections 24a to 24i in this example. The orientation of the grating 26 of each grid section 24a to 24i is the same in this example.

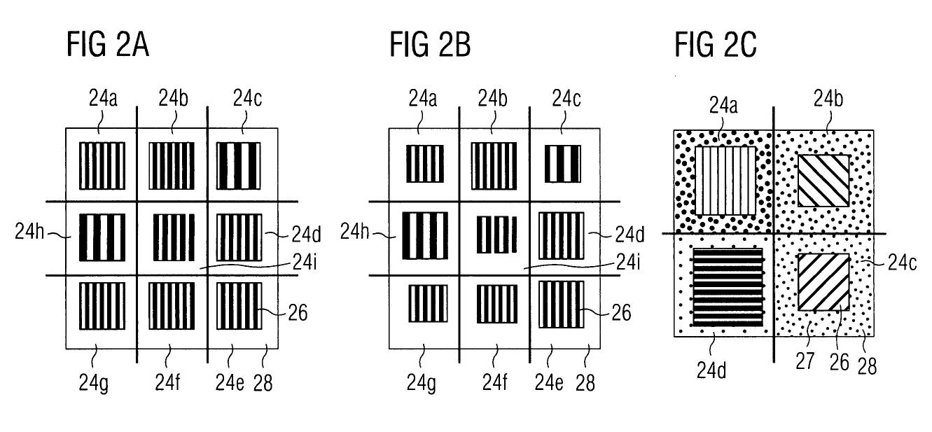

FIG. 2A illustrates a plan view of a section of a diffractive optical element 20 according to a further embodiment of the invention. Each grid section 24a to 24i has the same shape and size and comprises a grating 26 arranged in a central region and a non-grating region 28. Each grating 26 has the same size. The non-grating regions 28 are transparent. Each grid section 24a to 24i has predetermined grating parameters and absorption properties depending on the actual dimensions of the respectively corresponding mask sections of the photomask.

FIG. 2B illustrates a plan view of a section of a diffractive optical element 20 according to a further embodiment of the invention. Each grid section 24a to 24i has the same shape and size, wherein the gratings 26 and the respective non-grating regions 28 may have different sizes. The grid sections 24 comprise gratings 26 arranged in central regions of the grid sections 24, respectively, and transparent non-grating regions 28. The size of the gratings 26 differs from grid section 24a to 24i to grid section 24a to 24i. Thus, the size of the respective transparent region 28 differs for each grid section 24a to 24i resulting in different absorption properties. Each grid section 24a to 24i has defined grating parameters and absorption properties depending on the corresponding mask sections of the photomask.

FIG. 2C illustrates a plan view of a section of a diffractive optical element 20 according to a further embodiment of the invention. Each grid section 24a to 24i has the same shape and size. The grid sections 24 comprise gratings 26 arranged in central regions of the grid sections 24 respectively, and non-grating regions 28. The non-grating regions 28 comprise absorbing structures 27. The absorbing structures 27 are, by way of example, absorbing dots with a size of (1×1) μm² to (2×2) μm². The absorbing dots are homogeneously and (statistically) randomly distributed within the non-grating region 28 with a predetermined average density. The gratings 26 of respective grid sections 24a to 24d have different sizes. Thus the size of the non-grating regions 28 differs for grid sections 24a to 24d. Each grid section 24a to 24d has defined grating parameters and absorption properties depending on the corresponding mask sections of the photomask. Furthermore, the average density and the size of the absorbing structures 27 differ for each grid section 24, thus varying the absorption properties of the respective grid section 24.

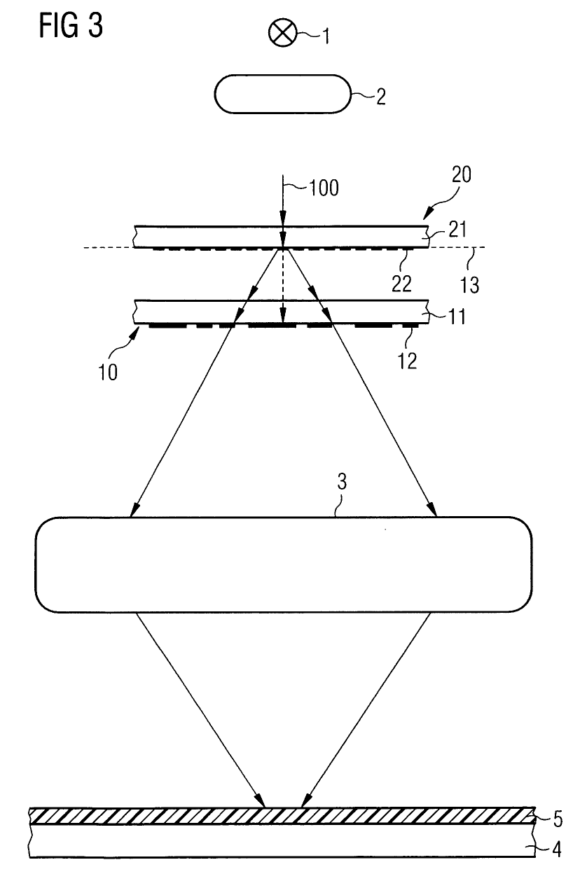

FIG. 3 illustrates an optical projection system according to an exemplary embodiment of the invention. The optical projection system comprises a light source 1, an illumination optic 2 defining the illumination source distribution and the polarization characteristics of the illumination light beam 100, a photomask 10 comprising a transparent mask substrate 11 and mask pattern elements 12 and a corresponding diffractive optical element 20 comprising a transparent element substrate 21 and grid pattern elements 22. The optical projection system comprises further a projection lens 3 for projecting the mask pattern elements 12 onto a photoresist layer 5 that covers a semiconductor wafer 4. The diffractive optical element 20 is positioned in an intermediate projection plane 13 of photomask 10 between illumination optic 2 and photomask 10, wherein a further lens (not shown) is positioned between diffractive optical element 20 and photomask 10.

Intermediate projection plane 13 is an optical conjugate plane to a plane of a conventional pellicle having a distance of 100 μm to 10 mm to the plane of mask pattern elements 12 of photomask 10 and being positioned between the plane of mask pattern elements 12 and illumination optic 2. Grid pattern elements 22 are projected in focus into this plane.

In one embodiment, the diffractive optical element 20 is maintained at a mechanical system (not shown), which is used to replace a first diffractive optical element 20 corresponding to a first photomask 10 by a second diffractive optical element 20 corresponding to a second photomask 10. Furthermore, the mechanical system carrying the diffractive optical element 20 moves corresponding to the motion of photomask 10 during the projection of mask pattern elements 12 into photoresist 5.

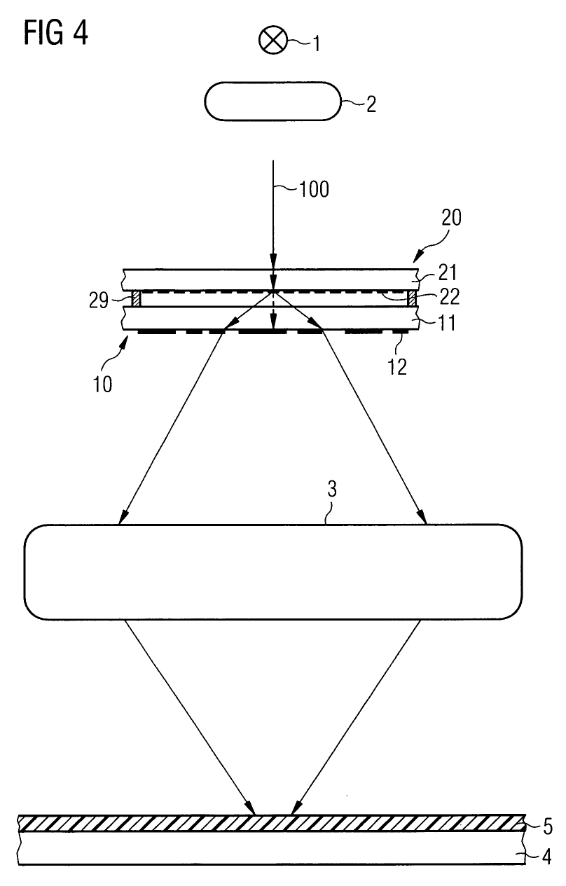

FIG. 4 illustrates an optical projection system according to another embodiment of the invention. The optical projection system comprises a light source 1, an illumination optic 2 defining the illumination source distribution and the polarization characteristics of an illumination light beam 100, a photomask 10 comprising a transparent mask substrate 11 and mask pattern elements 12, and a corresponding diffractive optical element 20 comprising a transparent element substrate 21 and grid pattern elements 22. The optical projection system further comprises a projection lens 3 for projecting the mask pattern elements 12 onto a photoresist layer 5 that covers a semiconductor wafer 4. A mounting frame 29 fixes the diffractive optical element 20 on that side of photomask 10 facing illumination optic 2.

FIG. 5 is a cross-sectional view of a diffractive optical element 20 and a corresponding photomask 10 being part of an optical projection system as shown in FIG. 4. A mounting frame 29 fixes the diffractive optical element 20 on a mask substrate 11 of photomask 10. Mask pattern elements 12 of photomask 10 may be disposed on that side of transparent mask substrate 11 of photomask 10 that faces a projection lens 3 as shown in FIG. 4. Grid pattern elements 22 of diffractive optical element 20 are disposed on that side of a transparent element substrate 21 of diffractive optical element 20 that faces photomask 10. Nevertheless, grid pattern elements 22 may be formed on the other side of diffractive optical element 20. Furthermore, grid pattern elements 22 may be formed within transparent element substrate 21 of diffractive optical element 20.

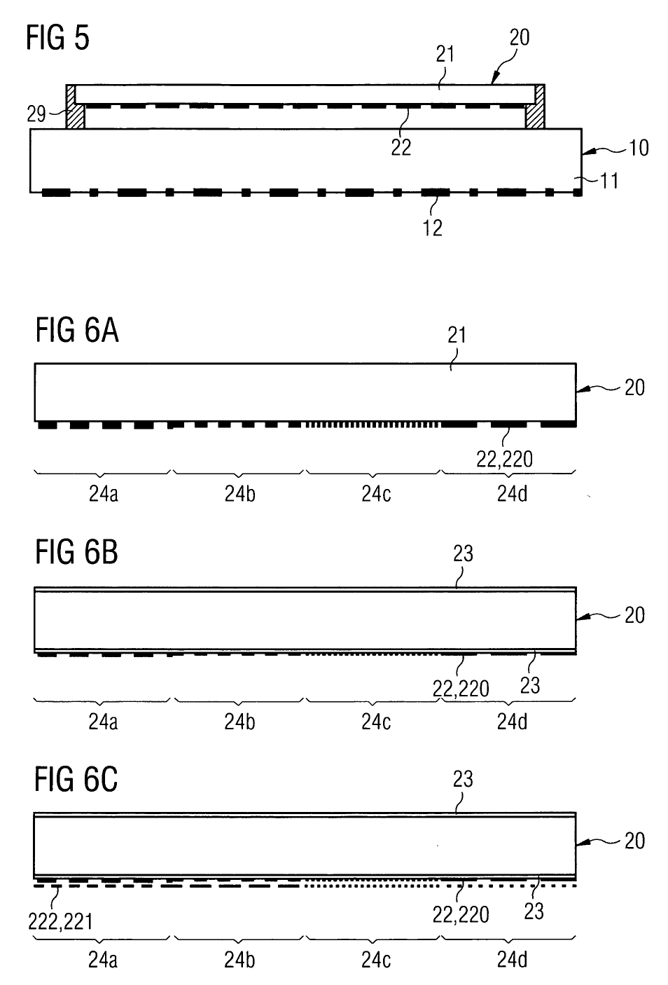

As shown in FIG. 6A, a diffractive optical element 20 comprises a transparent element substrate 21 and a grid layer 220 disposed on a surface of the element substrate 21. Within grid layer 220 grid pattern elements 22 comprising gratings and/or absorbing structures are formed. The material of grid layer 220 may be arbitrarily selected from materials that influence the illumination light beam in a predetermined way. For instance, MoSi or another semitransparent material or an opaque material like Cr may be used. Furthermore, transparent or semitransparent phase-shifting materials or layer stacks comprising one or more of the above-mentioned materials may be used. Grid pattern elements 22 of each grid section 24a to 24d, shown in FIG. 6A, form a grating with grating parameters and absorption properties such that resist pattern elements obtained from mask pattern elements in mask sections corresponding to the grid sections 24a to 24d of diffractive optical element 20 have predetermined dimensions.

As shown in FIG. 6B, an antireflective coating (ARC) layer 23 may be provided on both sides of a transparent element substrate 21 of a diffractive optical element 20. A grid layer 220 comprising grid pattern elements 22 is disposed on ARC layer 23. ARC layer 23 may also be disposed only on one side of element substrate 21.

The use of one or more ARC layers 23 may cause additional dimension deviations of resist pattern elements obtained from mask pattern elements 12. Process imperfections may cause local thickness variations of ARC layer 23 across the active area of diffractive optical element 20. The thickness of ARC layer 23 corresponds to the transmission efficiency of ARC layer 23 and thus influences the projection of mask pattern elements 12 onto a photoresist layer.

According to an exemplary embodiment, the correction of dimension deviations of resist pattern elements caused by variations in the thickness of ARC layer 23 is incorporated into the correction of dimension deviations caused by dimension variations of mask pattern elements 12 or caused by local deviations of the projection system. Dimension deviations caused by ARC layer 23 may be corrected by absorbing structures 27 comprised in grid sections 24 of diffractive optical element 20. The distribution and density of absorbing structures 27 of each grid section 24 corresponds to the required correction of transmission efficiency in respective sections of ARC layer 23. Thus the absorption properties of each grid section 24 are defined such that they correspond to respective mask sections of photomask 10 and respective layer sections of ARC layer 23.

According to another embodiment, as shown in FIG. 6C, a diffractive optical element 20 comprises a first grid layer 220 and a second grid layer 221. First grid layer 220 comprises grid pattern elements 22. The grating parameters and the absorption properties of the gratings and/or absorbing structures forming grid pattern elements 22 of grid layer 220 for each grid section 24 are defined such that they correct dimension deviations caused by dimension variations of mask pattern elements 12 or caused by local deviations of the projection system. Second grid layer 221 is disposed on first grid layer 220 as shown in FIG. 6C, but may also be disposed beneath first grid layer 220. Second grid layer 221 comprises grid pattern elements 222. Grid pattern elements 222 are absorbing structures having absorption properties for each grid section 24 defined such that they correct dimension deviations caused by variations in the thickness of ARC layer 23.

Both grid layers 220 and 221 may be formed on one side or on opposite sides of diffractive optical element 20.

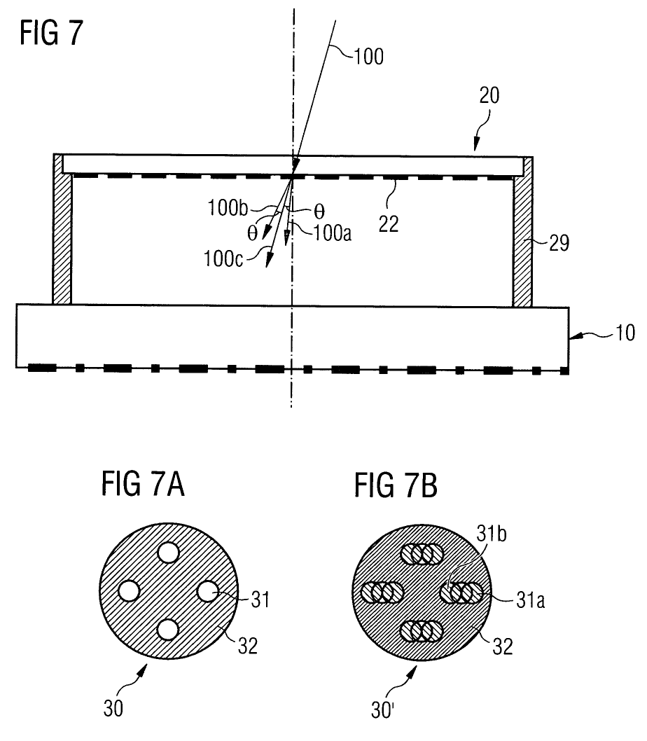

Referring to FIG. 7, the effect of a diffractive optical element 20 on the illumination source distribution of the projecting light is explained. A diffractive optical element 20 fixed on a photomask 10 is shown, but the effect is essentially the same if a diffractive optical element 20 is positioned in an intermediate projection plane of the photomask 10 as shown in FIG. 3.

As shown in FIG. 7, the illumination light beam 100 is diffracted by grid pattern elements 22 of the diffractive optical element 20 into a 0-order light beam 100c and in ± (plus/minus) 1^{st}-order light beams 100a and 100b. The diffracted light may include also higher order lights depending on the grating parameters of grid pattern elements 22. The angles of the diffracted light beams 100a and 100b are given by

sin(θ)=λ/P,

wherein λ is the wavelength of the light and P is the period of the grating lines of grid pattern elements 22.

FIG. 7A shows the illumination source distribution 30 of the incident illumination light beam 100 of FIG. 7. Illumination source distribution 30 is defined by illumination optic 2 of FIG. 3 or FIG. 4. By the way of example, a quadruple illumination source distribution 30 is shown having four light regions 31 and a dark region 32.

FIG. 7B shows the resulting corrected illumination source distribution 30′ of the light after passing a grid section with a linear (parallel lines) grating of a diffractive optical element 20. Corrected illumination source distribution 30′ is altered with respect to illumination source distribution 30 as shown in FIG. 7A due to the diffraction of light beam 100. Each light region 31 is spread along a first direction by two light regions 31a and 31b, wherein light region 31a results from the minus 1^{st}-order light beam 100a and light region 31b results from the plus 1^{st}-order light beam 100b. Nevertheless, other corrected illumination source distributions 30′ are possible depending on the grating parameters of grid pattern elements 22. Furthermore, the intensity of the diffracted light may be altered with respect to the intensity of incident illumination beam 100 by tuning the phase and the absorption properties of grid pattern elements 22.

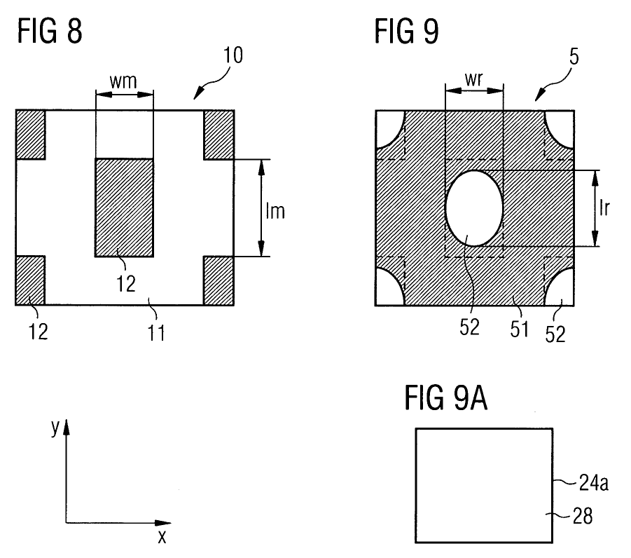

Referring now to FIGS. 8 to 11, the effect of a diffractive optical element 20 on the dimensions of resist pattern elements 52 is explained.

FIG. 8 shows a plan view of a section of a photomask 10 comprising opaque mask pattern elements 12 and a transparent mask substrate 11. The mask pattern elements 12 corresponding to contact structures in a contact layer of high-density array transistors are shown. Photomask 10 may comprise other mask pattern elements 12. The mask pattern elements 12 have a width wm measured in x-direction and a length lm measured in y-direction.

FIGS. 9 to 11 illustrate resist pattern elements 52 that are obtained from the mask pattern elements 12 as shown in FIG. 8. The resist pattern elements 52 may be unexposed regions of a photoresist layer 5 which are surrounded by an exposed region 51. The contours of the respectively corresponding mask pattern elements 12 are shown by the dashed lines. The resist pattern elements 52 have a width wr measured in x-direction and a length lr measured in y-direction.

In FIG. 9, wr is 75 nm and lr is 114.6 nm for example. The resist pattern elements 52 are obtained from a mask section corresponding to a grid section 24a of a diffractive optical element 20, wherein grid section 24a is shown in FIG. 9A. Grid section 24a comprises only a non-grating section 28 being transparent (non-absorbing). Differently stated, the grating parameters of a grating and the absorption properties of an absorbing element of grid section 24a are defined such that they do not change the projection of mask pattern elements 12 onto photoresist layer 5 by an optical projection system. These parameters are chosen since the resist pattern elements 52 have the desired dimensions.

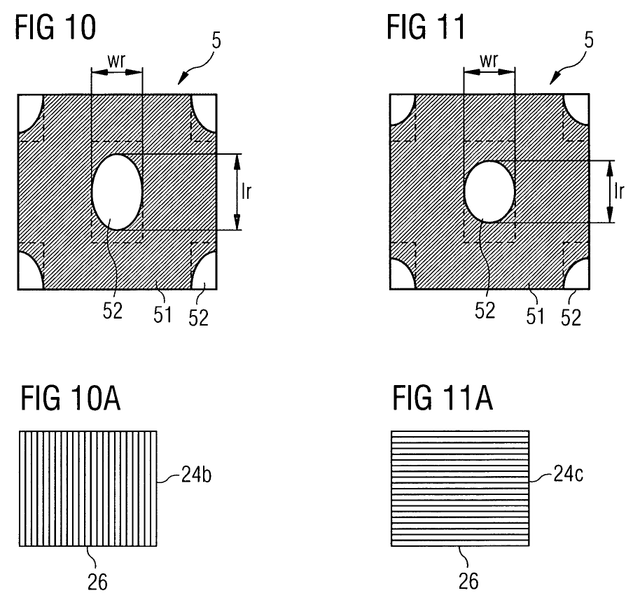

FIG. 10 shows resist pattern elements 52 obtained from a mask section corresponding to a grid section 24b of the diffractive optical element 20 according to FIG. 10A. Grid section 24b comprises a grating 26 with grating lines running along the y-direction. The dimensions of the resist pattern elements 52 are wr=75 nm and lr=125 nm. Thus, the lengths of resist pattern elements 52 are increased with respect to the lengths of resist pattern elements 52 of FIG. 9 due to the diffraction of the projecting light at the grating lines of grid section 24b without changing the widths of corresponding resist pattern elements 52.

FIG. 11 illustrates resist pattern elements 52 obtained from a mask section corresponding to a grid section 24c of the diffractive optical element 20, shown in FIG. 11A. The grid section 24c comprises a grating 26 with grating lines running along the x-direction. The dimensions of the resist pattern elements 52 are wr=75 nm and lr=102 nm. Thus, the lengths of resist pattern elements 52 are decreased with respect to the lengths of resist pattern elements 52 of FIG. 9 due to the diffraction of the projecting light at the grating lines of grid section 24c without changing the widths of corresponding resist pattern elements 52.

While the invention has been described in detail and with reference to specific embodiments thereof, it will be apparent to one skilled in the art that various changes and modifications can be made therein without departing from the spirit and the scope thereof. Accordingly, it is intended that the present invention covers the modifications and variations of this invention provided they come within the scope of the appended claims and their equivalents.

What is claimed is:

1. A mask arrangement for an optical projection system for projecting light absorber patterns onto a photoresist layer, comprising:
a photomask comprising a transparent mask substrate and a light absorber pattern, the light absorber pattern including at least a first mask section with a first mask pattern element and a second mask section with a second mask pattern element, wherein the first and the second mask pattern elements have essentially the same shape and size, wherein a first resist pattern element in the photoresist layer is obtained from the first mask pattern element and wherein a second resist pattern element in the photoresist layer is obtained from the second mask pattern element, wherein the first mask pattern element has a first length and a first width and the second mask pattern element has a second length and a second width, at least the second length or the second width being different from the first length and the first width respectively, and
a diffractive optical element positioned in an optical path between a light source of the optical projection system and the photomask, the diffractive optical element comprising at least a first grid section and a second grid section, the first grid section corresponding to the first mask section and comprising a first grating and a first absorbing element, the second grid section corresponding to the second mask section and comprising a second grating and a second absorbing element, wherein each grating shows grating parameters and each absorbing element shows absorption properties such that the first and the second resist pattern elements have the same length and width.

2. The mask arrangement of claim 1, wherein the diffractive optical element is fixed on the transparent mask substrate on a side facing the light source.

3. The mask arrangement of claim 1, wherein the diffractive optical element is positioned in an intermediate projection plane of the photomask between the photomask and optical elements defining the illumination source distribution of the optical projection system.

4. The mask arrangement of claim 1, wherein the diffractive optical element comprises a transparent element substrate and a grid layer disposed on the element substrate, the grid layer forming the first and second grid sections.

5. The mask arrangement of claim 1, wherein the diffractive optical element comprises a transparent grid substrate and wherein the gratings of the first and second grid sections are formed within the grid substrate.

6. The mask arrangement of claim 4, wherein the diffractive optical element further comprises at least one antireflective coating layer.

7. The mask arrangement of claim 1, wherein
the diffractive optical element comprises a transparent element substrate with a first surface facing the light source and a second surface facing the mask, an antireflective coating layer covering the first or the second surface of the element substrate, and a grid layer covering the antireflective coating layer or the surface of the element substrate not being covered by the antireflective coating layer;
the antireflective coating layer comprises a first layer section with a first thickness and a second layer section with a second thickness different from the first thickness; and
the first grid section of the diffractive optical element corresponds to the first layer section and the second grid section of the diffractive optical element corresponds to the second layer section.

8. The mask arrangement of claim 1, wherein
the diffractive optical element comprises a transparent element substrate with a first surface facing the light source and a second surface facing the mask, an antireflective coating layer covering the first or the second surface of the transparent element substrate, a first grid layer and a second grid layer, the first grid layer covering the antireflective coating layer and the second grid layer covering the first grid layer or the surface of the element substrate not being covered by the antireflective coating layer;
the antireflective coating layer comprises a first layer section with a first thickness and a second layer section with a second thickness different from the first thickness; and
the first grid section of the diffractive optical element corresponds to the first layer section and comprises the first grating and the first absorbing element in the first grid layer and a third absorbing element in the second grid layer, the second grid section of the diffractive optical element corresponds to the second layer section and comprises the second grating and the second absorbing element in the first grid layer and a fourth absorbing element in the second grid layer, and each grating has grating parameters and each absorbing element has absorption properties such that the first and the second resist pattern elements have the same length and width.

9. The mask arrangement of claim 1, wherein the diffractive optical element comprises a plurality of grid sections having the same shape and the same size, each grid section comprising a grating with grating parameters and an absorbing element with absorption properties such that resist pattern elements obtained from mask pattern elements corresponding to the grid sections have predetermined dimensions.

10. The mask arrangement of claim 9, wherein at least one grid section comprises a non-grating region and a region with a grating.

11. An optical projection system for projecting light absorber patterns onto a photoresist layer, comprising:
an illumination system including a light source emitting light;
optical elements defining an illumination source distribution and a polarization characteristic of the light;
a photomask positioned in an optical path of the illumination system, the photomask comprising a transparent mask substrate and a light absorber pattern, the light absorber pattern having at least a first mask section with a first mask pattern element and a second mask section with a second mask pattern element, wherein a first resist pattern element in the photoresist layer is obtained from the first mask pattern element and wherein a second resist pattern element in the photoresist layer is obtained from the second mask pattern element;
a projection lens for projecting the patterns of the photomask onto the photoresist layer on a surface of a substrate; and
a diffractive optical element positioned in the optical path between the light source of the illumination system and the photomask, the diffractive optical element comprising at least a first grid section and a second grid section, the first grid section corresponding to the first mask section and comprising a first grating and a first absorbing element, and the second grid section corresponding to the second mask section and comprising a second grating and a second absorbing element, wherein each grating shows grating parameters and each absorbing element shows absorption properties such that the first resist pattern element has a length and a width in a predetermined ratio to the length and the width of the second resist pattern element.

12. The optical projection system of claim 11, wherein the diffractive optical element is fixed on the transparent mask substrate on a side that faces the light source.

13. The optical projection system of claim 11, wherein the diffractive optical element is positioned in an intermediate projection plane of the photomask between the photomask and the optical elements.

14. The optical projection system of claim 13, wherein the diffractive optical element is fixed to a mechanical system moving corresponding to a motion of the photomask.

15. The optical projection system of claim 11, wherein the diffractive optical element comprises a transparent element substrate and a grid layer disposed on the element substrate, the grid layer comprising the first and second grid sections.

16. The optical projection system of claim 11, wherein the diffractive optical element comprises a transparent grid substrate and wherein the gratings of the first and second grid sections are formed within the transparent grid substrate.

17. The optical projection system of claim 15, wherein the diffractive optical element further comprises at least one antireflective coating layer.

18. The optical projection system of claim 11, wherein:
the diffractive optical element comprises a transparent element substrate with a first surface facing the light source and a second surface facing the mask, an antireflective coating layer covering the first or the second surface of the element substrate, and a grid layer covering the antireflective coating layer or the surface of the element substrate not being covered by the antireflective coating layer;
the antireflective coating layer comprises a first layer section with a first thickness and a second layer section with a second thickness different from the first thickness; and
the first grid section of the diffractive optical element corresponds to the first layer section and the second grid section of the diffractive optical element corresponds to the second layer section.

19. The optical projection system of claim 11, wherein:
the diffractive optical element comprises a transparent element substrate with a first surface facing the light source and a second surface facing the mask, an antireflective coating layer covering the first or the second surface of the transparent element substrate, a first grid layer and a second grid layer, the first grid layer covering the antireflective coating layer and the second grid layer covering the first grid layer or the surface of the element substrate not being covered by the antireflective coating layer;
the antireflective coating layer comprises a first layer section with a first thickness and a second layer section with a second thickness different from the first thickness; and
the first grid section of the diffractive optical element corresponds to the first layer section and comprises the first grating and the first absorbing element in the first grid layer and a third absorbing element in the second grid layer, the second grid section of the diffractive optical element corresponds to the second layer section and comprises the second grating and the second absorbing element in the first grid layer and a fourth absorbing element in the second grid layer, and each grating has grating parameters and each absorbing element has absorption properties such that the first resist pattern element has a length and a width in a predetermined ratio to the length and the width of the second resist pattern element.

20. The optical projection system of claim 19, wherein the first and the second resist pattern elements have the same length and have the same width.

21. The optical projection system of claim 11, wherein the diffractive optical element comprises a plurality of grid sections having the same shape and the same size, each grid section comprising a grating with grating parameters and an absorbing element with absorption properties such that resist pattern elements obtained from mask pattern elements corresponding to the respective grid sections have predetermined dimensions.

22. The optical projection system of claim 21, wherein at least one grid section comprises a non-grating region and a region with a grating.

23. The optical projection system of claim 11, wherein:
imperfections of the optical elements or the projection lens cause deviations in the illumination source distribution and/or the polarization characteristic and/or the projection of the mask pattern elements; and
the first and second mask pattern elements have the same length and have the same width, and the first and second resist pattern elements have the same length and have the same width.

24. The optical projection system of claim 11, wherein:
wherein imperfections of the optical elements or the projection lens cause deviations in the illumination source distribution and/or the polarization characteristic and/or the projection of the mask patterns;
a length of the first mask pattern element differs from a length of the second mask pattern element or a width of the first mask pattern element differs from a width of the second mask pattern element; and
the first and second resist pattern elements have the same length and the same width.

25. The optical projection system of claim 11, wherein:
a length of the first mask pattern element is in a predetermined ratio to a length of the second mask pattern element, and a width of the first mask pattern is in a predetermined ratio to a width of the second mask pattern element; and
projections of the first and second mask pattern elements differ from each other.

26. A method for obtaining the grating parameters and absorption properties of the diffractive optical element of the mask arrangement of claim 1, comprising:
determining dimensions of the mask pattern elements;
calculating first dimensions of resist pattern elements using a simulation program, the resist pattern elements being obtained from the respective mask pattern elements by projection onto a photoresist, wherein a virtual diffractive optical element with first grating parameters and first absorption properties of each grid section is supposed in a simulated optical path of the simulation program;
comparing the first dimensions of the resist pattern elements with predetermined dimensions of the resist pattern elements;
varying the grating parameters and the absorption properties of the grid sections of the virtual diffractive optical element in dependency on the difference between the calculated and the predetermined dimensions of the resist pattern elements;
calculating second dimensions of the resist pattern elements using the simulation program on base of varied grating parameters and absorption properties of the virtual diffractive optical element;
repeating of comparing the calculated dimensions with predetermined dimensions, varying the grating parameters and absorption properties and calculating the dimensions of the resist pattern elements obtained from mask pattern elements as long as the predetermined dimensions of the resist pattern elements are not obtained; and
storing the last grating parameters and the last absorptions properties of each grid section of the virtual diffractive optical element, if the predetermined dimensions of the resist pattern elements are obtained, wherein the last grating parameters and the last absorption properties of the grid sections of the virtual diffractive optical element are equal to the grating parameters and absorption properties of the grid sections of the diffractive optical element.

27. The method of claim 26, wherein determining the dimensions of the mask pattern elements comprises measuring the dimensions of the mask pattern elements in the photomask.

29. The method of claim 26, wherein determining the dimensions of the mask pattern elements comprises:
providing at least two different photoresist layers;
projecting the mask patterns onto the photoresist layers using at least two different optical projection systems;
developing the photoresist layers thereby obtaining resist pattern elements;
measuring the dimensions of the resist pattern elements;
comparing the measured dimensions of the resist pattern elements obtained from the same mask pattern elements projected by different optical projection systems, thereby eliminating the differences in the measured dimensions caused by deviations in the optical projection systems; and
calculating the dimensions of the mask pattern elements in the photomask and storing these dimensions.

30. A method for obtaining the grating parameters and absorption properties of the diffractive optical element of the mask arrangement of claim 7, comprising:
determining the dimensions of the mask pattern elements;
providing an initial optical element comprising the transparent element substrate and the at least one antireflective coating layer of the diffractive optical element;
determining the transmission properties of each element section of the initial optical element, each element section corresponding to respective grid sections of the diffractive optical element and to respective layer sections of the antireflective coating layer;
calculating first dimensions of the resist pattern elements using a simulation program, the resist pattern elements being obtained from the respective mask pattern elements by projection onto a photoresist, wherein a virtual diffractive optical element with first grating parameters and first absorption properties of each grid section is supposed in a simulated optical path and wherein the simulation program incorporates the determined transmission properties of each element section;
comparing the first dimensions of the resist pattern elements with predetermined dimensions of the resist pattern elements;
varying the grating parameters and absorption properties of the grid sections of the virtual diffractive optical element in dependency on the difference between the calculated and the predetermined dimensions of the resist pattern elements;
calculating second dimensions of the resist pattern elements using the simulation program wherein the virtual diffractive optical element with varied grating parameters and absorption properties is supposed;
repeating of comparing the calculated dimensions with predetermined dimensions, varying the grating parameters and absorption properties and calculating the dimensions of the resist pattern elements obtained from mask pattern elements as long as the predetermined dimensions of the resist pattern elements are not obtained; and
storing the last grating parameters and the last absorptions properties of each grid section of the virtual diffractive optical element, if the predetermined dimensions of the resist pattern elements are obtained, wherein the last grating parameters and the last absorption properties of the grid sections of the virtual diffractive optical element are equal to the grating parameters and absorption properties of the grid sections of the diffractive optical element.

31. A method for obtaining the grating parameters and the absorption properties of a diffractive optical element of the optical projection system of claim 11, comprising:
projecting mask pattern elements in the photomask onto respective sections of the photoresist layer using the optical projection system;
developing the photoresist layer thereby obtaining resist pattern elements;
measuring the dimensions of the resist pattern elements;
comparing the measured dimensions of the resist pattern elements obtained from different sections of the photomask, thereby eliminating the differences in the measured dimensions caused by differences in the dimensions of the mask pattern elements within the different sections of the photomask;
calculating the deviations caused by imperfections of the optical elements or of the projection lens means of the optical projection system and storing these deviations;
calculating first dimensions of resist pattern elements using a simulation program, the resist pattern elements being obtained from mask pattern elements in a photomask by projection onto a photoresist, the mask pattern elements having equal dimensions, wherein a virtual diffractive optical element with first grating parameters and first absorption properties of each grid section is supposed in the optical path of the projection system and wherein the simulation program incorporates the stored deviations caused by the projection system;
comparing the first dimensions of the resist pattern elements with predetermined dimensions of the resist pattern elements;
varying the grating parameters and absorption properties of the grid sections of the virtual diffractive optical element in dependency on the difference between the calculated and the predetermined dimensions of the resist pattern elements;
calculating second dimensions of the resist pattern elements using the simulation program wherein the virtual diffractive optical element with varied grating parameters and absorption properties is supposed in the optical path;
repeating of comparing the calculated dimensions with predetermined dimensions, varying the grating parameters and absorption properties and calculating the dimensions of the resist pattern elements obtained from the mask pattern elements as long as the predetermined dimensions of the resist pattern elements are not obtained; and
storing the last grating parameters and the last absorptions properties of each grid section of the virtual diffractive optical element, if the predetermined dimensions of the resist pattern elements are obtained, wherein the last grating parameters and the last absorption properties of the grid sections of the virtual diffractive optical element are equal to the grating parameters and absorption properties of the grid sections of the diffractive optical element.

32. A method for obtaining the grating parameters and the absorption properties of a diffractive optical element of the optical projection system of claim 18, comprising:
projecting mask pattern elements in the photomask onto respective sections of the photoresist layer using the optical projection system;
developing the photoresist layer thereby obtaining resist pattern elements;
measuring the dimensions of the resist pattern elements;
comparing the measured dimensions of the resist pattern elements obtained from different sections of the photomask, thereby eliminating the differences in the measured dimensions caused by differences in the dimensions of the mask pattern elements within the different sections of the photomask;
calculating the deviations caused by imperfections of the optical elements or of the projection lens means of the optical projection system and storing these deviations;
providing an initial optical element comprising the transparent element substrate and the at least one antireflective coating layer of the diffractive optical element;
determining the transmission properties of each element section of the initial optical element, each element section corresponding to a respective grid section of the diffractive optical element and to a respective layer section of the antireflective coating layer;
calculating first dimensions of resist pattern elements using a simulation program, the resist pattern elements being obtained from mask pattern elements in a photomask by projection onto a photoresist, the mask pattern elements having equal dimensions, wherein a virtual diffractive optical element with first grating parameters and first absorption properties of each grid section is supposed in the simulated optical path and wherein the simulation program incorporates the stored deviations caused by the projection system and the determined transmission properties of each element section;
comparing the first dimensions of the resist pattern elements with predetermined dimensions of the resist pattern elements;
varying the grating parameters and absorption properties of the grid sections of the virtual diffractive optical element in dependency on the difference between the calculated and the predetermined dimensions of the resist pattern elements;
calculating second dimensions of the resist pattern elements using the simulation program wherein the virtual diffractive optical element with varied grating parameters and absorption properties is supposed;
repeating of comparing the calculated dimensions with predetermined dimensions, varying the grating parameters and absorption properties and calculating the dimensions of the resist pattern elements obtained from the mask pattern elements as long as the predetermined dimensions of the resist pattern elements are not obtained; and
storing the last grating parameters and the last absorptions properties of each grid section of the virtual diffractive optical element, if the predetermined dimensions of the resist pattern elements are obtained, wherein the last grating parameters and the last absorption properties of the grid sections of the virtual diffractive optical element are equal to the grating parameters and absorption properties of the grid sections of the diffractive optical element.

33. A method for obtaining the grating parameters and the absorption properties of a diffractive optical element of the optical projection system of claim 11, comprising:
projecting mask pattern elements in the photomask onto the photoresist layer using the optical projection system;
developing the photoresist layer thereby obtaining resist pattern elements;
measuring the dimensions of the resist pattern elements;
calculating first dimensions of the resist pattern elements obtained from the respective mask pattern elements in the photomask by projection onto a photoresist through the optical projection system using a simulation program with first program parameters;
comparing the first dimensions of the resist pattern elements with the measured dimensions of the resist pattern elements;
varying the program parameters of the simulation program in dependency on the difference between the calculated and the measured dimensions of the resist pattern elements;
calculating second dimensions of the resist pattern elements obtained from the mask pattern elements in the photomask by projection onto a photoresist through the optical projection system using the simulation program with varied program parameters;
repeating of comparing the calculated dimensions with the measured dimensions, varying the program parameters and calculating the dimensions of the resist pattern elements as long as the calculated dimensions of the resist pattern elements are not equal to the measured dimensions of the resist pattern elements;
storing the last program parameters of the simulation program, if the calculated dimensions of the resist pattern elements are equal to the measured dimensions of the resist pattern elements;
calculating third dimensions of resist pattern elements obtained from the respective mask pattern elements in the photomask by projection onto a photoresist using a simulation program with the stored program parameters, wherein a virtual diffractive optical element with first grating parameters and first absorption properties of each grid section is supposed in the optical path;
comparing the third dimensions of the resist pattern elements with predetermined dimensions of the resist pattern elements;
varying the grating parameters and absorption properties of the grid sections of the virtual diffractive optical element in dependency on the difference between the calculated and the predetermined dimensions of the resist pattern elements
calculating fourth dimensions of the resist pattern elements obtained from the mask pattern elements in the photomask by projection onto a photoresist using the simulation program, wherein the virtual diffractive optical element with varied grating parameters and absorption properties is supposed in the optical path;
repeating of comparing the calculated dimensions with predetermined dimensions, varying the grating parameters and absorption properties and calculating the dimensions of the resist pattern elements obtained from the mask pattern elements as long as the predetermined dimensions of the resist pattern elements are not obtained; and
storing the last grating parameters and the last absorptions properties of each grid section of the diffractive optical element, if the predetermined dimensions of the resist pattern elements are obtained, wherein the last grating parameters and the last absorption properties of the grid sections of the virtual diffractive optical element are equal to the grating parameters and absorption properties of the grid sections of the diffractive optical element.

34. A method for obtaining the grating parameters and the absorption properties of a diffractive optical element of the optical projection system of claim 18, comprising:
projecting mask pattern elements in the photomask onto the photoresist layer using the optical projection system;
developing the photoresist layer thereby obtaining resist pattern elements;
measuring the dimensions of the resist pattern elements;
calculating first dimensions of the resist pattern elements obtained from the respective mask pattern elements in the photomask by projection onto a photoresist through the optical projection system using a simulation program with first program parameters;
comparing the first dimensions of the resist pattern elements with the measured dimensions of the resist pattern elements;
varying the program parameters of the simulation program in dependency on the difference between the calculated and the measured dimensions of the resist pattern elements;
calculating second dimensions of the resist pattern elements obtained from the mask pattern elements in the photomask by projection onto a photoresist through the optical projection system using the simulation program with varied program parameters;
repeating of comparing the calculated dimensions with the measured dimensions, varying the program parameters and calculating the dimensions of the resist pattern elements as long as the calculated dimensions of the resist pattern elements are not equal to the measured dimensions of the resist pattern elements;
storing the last program parameters of the simulation program, if the calculated dimensions of the resist pattern elements are equal to the measured dimensions of the resist pattern elements;
providing an initial optical element comprising the transparent element substrate and the at least one antireflective coating layer of the diffractive optical element;
determining the transmission properties of each element section of the initial optical element, each element section corresponding to a respective grid section of the diffractive optical element and to a respective layer section of the antireflective coating layer;
calculating third dimensions of resist pattern elements obtained from the respective mask pattern elements in the photomask by projection onto a photoresist using a simulation program with the stored program parameters, wherein a virtual diffractive optical element with first grating parameters and first absorption properties of each grid section is supposed in the optical path and wherein the simulation program incorporates the determined transmission properties of each element section of the initial optical element;
comparing the third dimensions of the resist pattern elements with predetermined dimensions of the resist pattern elements;
varying the grating parameters and absorption properties of the grid sections of the virtual diffractive optical element in dependency on the difference between the calculated and the predetermined dimensions of the resist pattern elements;
calculating fourth dimensions of the resist pattern elements obtained from the mask pattern elements in the photomask by projection onto a photoresist using the simulation program, wherein the virtual diffractive optical element with varied grating parameters and absorption properties is supposed in the optical path;
repeating of comparing the calculated dimensions with predetermined dimensions, varying the grating parameters and absorption properties and calculating the dimensions of the resist pattern elements obtained from the mask pattern elements as long as the predetermined dimensions of the resist pattern elements are not obtained; and
storing the last grating parameters and the last absorptions properties of each grid section of the diffractive optical element, if the predetermined dimensions of the resist pattern elements are obtained, wherein the last grating parameters and the last absorption properties of the grid sections of the virtual diffractive optical element are equal to the grating parameters and absorption properties of the grid sections of the diffractive optical element.
